(19) United States
(12) Patent Application Publication
(10) Pub. No.: US 2019/0199271 A1
(43) Pub. Date: Jun. 27, 2019

(54) IMPROVED SOLAR MODULE MOUNTING SYSTEMS USING A MODULE CONNECTOR AND PROCESSES THEREOF

(71) Applicant: Giga Solar FPC, Inc., Portola Valley, CA (US)

(72) Inventors: Thomas G. HOOD, Portola Valley, CA (US); Sicco WESTRA, Arroyo Grande, CA (US)

(73) Assignee: Giga Solar FPC, Inc., Portola Valley, CA (US)

(21) Appl. No.: 16/327,867

(22) PCT Filed: Aug. 23, 2017
(86) PCT No.: PCT/US17/48101

§ 371 Date: Feb. 25, 2019

Related U.S. Application Data
(60) Provisional application No. 62/378,646, filed on Aug. 23, 2016.

(51) Int. Cl. H02S 20/23

(52) U.S. Cl. CPC H02S 20/23; H01L 31/042

(57) ABSTRACT

A mounting system for mounting a solar module to a support structure is described. The mounting system includes one or more module connectors that couple one or more support rails, to one or more module rails.

### RELATED APPLICATION

The application claims priority from U.S. Provisional Application having Ser. No. 62/378,646 filed on Aug. 23, 2016, which is incorporated herein by reference for all purposes.

### FIELD

The present teachings generally relate to module mounting systems and processes relating thereto. More particularly, the present teachings relate to systems and processes for mounting one or more modules (e.g., solar modules) using a module connector to a support structure, such as a rooftop.

### BACKGROUND

Conventional solar module mounting systems use numerous interconnecting components to mount one or more solar module to a support structure. Unfortunately, they are typically heavy and involve a cumbersome assembly process. Additionally, they do not allow modules to be installed adjacent to each other, and, therefore, consume an inordinate amount of real estate on the support structure. These drawbacks of the conventional solar module mounting design detract from the renewable energy advantages obtained from solar cell applications. By way of example, heavy and complicated conventional module mounting systems suffer from increased transportation costs and installation costs. To this end, specialized equipment such as lifts or cranes are typically needed to lift components of the module mounting systems from the ground to a support structure (e.g., rooftop) typically located high above the ground. Moreover, complicated designs, which require numerous components, prolong the solar module installation process. As another example, the inordinate amount of real estate consumed by the conventional mounting systems prevents a requisite number of modules to be installed in a particular area of the support structure. Without the installation of a sufficient number of solar modules, the advantages of renewable solar energy are not realized. This problem is further exacerbated when the support structure does not include a large surface area to begin with.

What is, therefore, needed are novel systems and processes for effectively mounting modules to support structures that do not suffer from the drawbacks encountered by the conventional mounting designs.

### SUMMARY OF THE INVENTION

To this end, the present arrangements and teachings provide lightweight module mounting systems and processes relating thereto. The present mounting systems effectively and simply install and secure multiple modules adjacent to each other with minimal or no gap between each module.

In one aspect, the present arrangements provide improved module mounting systems. One such exemplar module mounting system includes: (1) one or more support rails; (2) one or more module rails; and (3) one or more module connectors.

Each support structure is designed to attach to a support structures (e.g., rooftop) and includes an extending portion. Each module rail is designed to attach to one or more modules and includes an engaging surface and sidewalls that are configured to define, inside the module rail, a channel cavity. Furthermore, the sidewalls of each module rail include one or more internal lip features that extend towards and along a length of the channel cavity. Each internal lip feature defines one or more locking surfaces.

Each module connector is designed to couple at least one support rail to at least one module rail. Moreover, the module connector includes a support structure receiving portion having defined therein a receiving cavity, which has one or more inner receiving surfaces. Additionally, each module connector includes an outer boundary of a contacting surface, and further includes one or more connecting portions, each of which includes one or more lockable surfaces.

In an assembled configuration of one exemplar present mounting system, one or more module connectors are inserted into one or more module rails such that contacting surface of each module connectors contacts an engaging surface of one module rail and/or another module rail. Further, one or more lockable surfaces of each module connector engage with one or more locking surfaces of one module rail and/or another module rail. The engagement between the lockable surface and the locking surfaces lock one or more module connectors inside one or more module rails. Additionally, an extending portion of each support rail is received inside the receiving cavity of each module connector. In this configuration, one or more module connectors couple to one or more support attachment rails.

In one preferred embodiment of the present arrangements, one end of one of the module rail includes a notch to facilitate connection of one module rail with another module rail and is designed to receive the support rail. In another preferred embodiment of the present arrangements, internal lip features of the module rail include open edges. Each open edge has a curved profile that bends towards an extending portion and/or channel cavity. In yet another preferred embodiment of the present arrangements, the module rail is fastened to a solar module using a module fastening assembly.

In one embodiment to the present arrangements, the support structure is a rafter of a roof structure. In an attached configuration of the support structure and the support rail, the support rail is disposed in a direction that is perpendicular to an extending direction of the rafter. Preferably, each support rail is secured to multiple rafters.

In another embodiment of the present arrangements, the extending portion of each support rail has protruding sidewalls that are designed to contact the inner receiving surfaces a module connector. Preferably, dimensions of the inner receiving surfaces of each module connector are slightly larger than dimensions of the protruding sidewalls of each support rail. In assembled configuration of the present mounting systems, the protruding sidewalls are secured inside one of the inner receiving surfaces by frictional contact. More preferably, the protruding sidewalls are secured inside the inner receiving surfaces by a fastening assembly that fastens one of the protruding sidewalls to one of the inner receiving surfaces. In yet another implementation of the present arrangements, approximate open edges of a support rail's extending portion includes one or more support internal lip features, each of which includes a curved profile bending towards the extending portion and/or simple profile that does not include a curved profile. The curved profile defines a pathway for fasteners that facilitates simply and rapid coupling of the support structure and the support rail.

The mounting systems, in one embodiment further includes a support fastening assembly that fastens the support rail to a support structure such that a space is defined between the support rail and the support structure to allows for moisture or rain to travel.

A module connector, in one embodiment of the present arrangements, includes a first connecting portion having a connector fin, which has one or more lockable surfaces. In an assembled configuration of the present mounting system, one or more lockable surfaces of the connector fin engage with one or more locking surfaces of the module rail.

In another embodiment of the present arrangements, the module connector includes a second connection portion having an additional contacting surface and external sidewalls, which have, at a location approximate to an end, one or more additional lockable surfaces. In assembled configuration of a module connector and a module rail, one or more of the additional lockable surfaces engage with one or more of the locking surfaces of the module rail.

In another embodiment of the present arrangements, the inner receiving surface of the module rail is defined by two or more opposing sidewalls

The contacting surface of each module connectors, in certain embodiments of the present arrangements, contacts the engaging surface of a module rail and/or another module rail. In another embodiment of the present arrangements, one or more lockable surfaces of each module connectors engages with one or more locking surfaces of one module rail and/or another module rail.

In yet another aspect, the present teachings provide a process for mounting a module. The process of mounting a module may begin with a step (i). This step includes obtaining one or more module rails. A module rail includes an engaging surface and sidewalls that are configured to define, inside each module rail, a channel cavity. The sidewalls include one or more internal lip features that extend towards and along a length of the channel cavity, and the internal lip features define one or more locking surfaces.

Next, a step (ii) is carried out. This step includes securing to one or more modules one or more of said module rails to form one or more module sub-assemblies.

Then, step (iii) may follow or is carried out prior to step (ii) and includes obtaining one or more support rails, each of which includes an extending portion.

Following step (iii), in a next step (iv) support connecting subassemblies may be formed. Specifically, this step includes coupling to one or more support structures one or more support structure attachment rails to form one or more support connecting subassemblies.

Once module subassemblies and support connecting subassemblies are formed, they are ready for coupling. To this end, step (v) includes connecting, using one or more module connectors, one or more module subassemblies and one or more support connecting subassemblies. A module connector includes a support structure receiving portion that has defined therein a receiving cavity having inner receiving surfaces. A module connector also includes an outer boundary of a contacting surface and one or more connecting portions, each of which includes one or more lockable surfaces. In one embodiment of the present teachings, connecting includes inserting one or more module connectors into one or more module rails. In this assembled configuration, the contacting surface of each module connector contacts the engaging surface of one and/or another module rail and one or more lockable surfaces of each module connector engages with one or more locking surfaces of one and/or another module rails to lock one or more module connectors inside one or more module rails. In another embodiment of the present teachings, connecting further includes receiving the extending portion of each support rail inside each receiving cavity of each module. In this assembled configuration, one or more module connectors couple to one or more support attachment rails.

In one embodiment of the present teachings, coupling or securing involves using an adhesive and/or a fastening assembly. The present teachings and arrangements also recognize that the above-mentioned process steps need not be carried out in the order or sequence described above and may be carried out in any number of other orders or sequences. By way of example, one or more of the support connecting subassemblies are formed prior to forming one or more of the module subassemblies.

The construction and method of operation of the present teachings and arrangements, however, together with additional objects and advantages thereof, will be best understood from the following descriptions of specific embodiments when read in connection with the accompanying figures.

### BRIEF DESCRIPTION OF THE DRAWINGS

FIG. 1A shows cross-sectional view of a support rail, according to one embodiment of the present arrangements, for attaching to a support structure, such as a rooftop, on one side and for attaching to a module connector on another side, and the support rail includes a lip portion disposed at the end of sidewalls that define a cavity near a center region of the support rail.

FIG. 1B shows an isometric view of the support rail shown in FIG. 1A.

FIG. 2A shows cross-sectional view of a support rail, according to another embodiment of the present arrangements and that does not include a lip portion disposed at the end of sidewalls that define a cavity near a center region of the support rail.

FIG. 2B shows an isometric view of the support rail of FIG. 2A.

FIG. 3 shows a cross-sectional view of a support connecting subassembly, according to one embodiment of the present arrangements, and that includes the support rail of FIG. 1A that is coupled to a support structure.

FIG. 4 shows a top view of a mounting subassembly, according to one embodiment of the present arrangements and that includes multiple support connecting subassemblies of FIG. 3 overlying a rooftop structure, which includes multiple rafters disposed in a direction perpendicular to the extending directions of the support rails.

FIG. 5 shows a cross-sectional view of a module rail, according to one embodiment of the present arrangements and that couples to a module connector at one end and couples to a module (e.g., solar module) at another end.

FIG. 6 shows a side-sectional view of a module subassembly, according to one embodiment of the present arrangements and that includes two module rails of FIG. 5 coupled to a module, and at least one of the module rails include a notched region that facilitates the coupling of two different modules and/or coupling of a module and a support structure.

FIG. 7 shows a cross-sectional view of the module subassembly of FIG. 5, according to one embodiment of the present arrangements and that includes two module rails coupled to a module, and the two module rails facilitates connection to another module subassembly and/or coupling of a module to a support structure.

FIG. 8 shows a cross-sectional view of a module connector, according to one embodiment of the present arrangements and that, in one assembled configuration of the present mounting system, couples a module rail to a support rail.

FIG. 9 shows a cross-sectional view of a module connector, according to another embodiment of the present arrangements and that includes a connector fin, and that, in one assembled configuration of the present mounting system, couples one module rail to another module rail, and couples one or more module rails to a support rail.

FIG. 10 shows a cross-sectional view of a module connector, according to yet another embodiment of the present arrangements and that includes a connector fin and a framed connecting portion, and that, in one assembled configuration of the present mounting system, couples one module rail to another module rail, and couples one or more module rails to a support rail.

FIG. 11A shows an exploded cross-sectional view of a mounting system subassembly, according to one embodiment of the present arrangements and that includes a module connector that is capable of securing two module subassemblies to a support connecting subassembly.

FIG. 11B shows cross-sectional view of a mounting system subassembly of FIG. 11A in an assembled configuration.

FIG. 12 shows a cross-sectional view of multiple mounting system subassemblies, according to one embodiment of the present arrangements and that are arranged to secure two adjacent modules.

FIG. 13 shows a top view of a module mounting system, according to one embodiment of the present arrangements and that has mounted thereon numerous modules in a grid-like fashion.

### DETAILED DESCRIPTION OF THE DRAWINGS

In the following description, numerous specific details are set forth in order to provide a thorough understanding of the present teachings and arrangements. It will be apparent, however, to one skilled in the art that the present teachings and arrangements may be practiced without limitation to some or all of these specific details. In other instances, well-known process steps have not been described in detail in order to not unnecessarily obscure the present teachings and arrangements.

The present teachings and arrangements provide improved module support systems and processes relating thereto that are discussed in greater detail below. In one preferred embodiment of the present arrangements, the mounting systems include one or more module connectors and rails, which couple to one or more modules and that couple to one or more support structures. In this embodiment, the module connector effectively functions as an intermediate component that couples rails associated with modules to those that are associated with the support structures. For sake of clarity, rails associated with modules are hereinafter referred to as module rails and in one assembled configuration of the mounting systems, the module rails couple to modules. Similarly, rails associated with support structures are hereinafter referred to as support rails and in one assembled configuration of the mounting systems, the support rails couple to support structures.

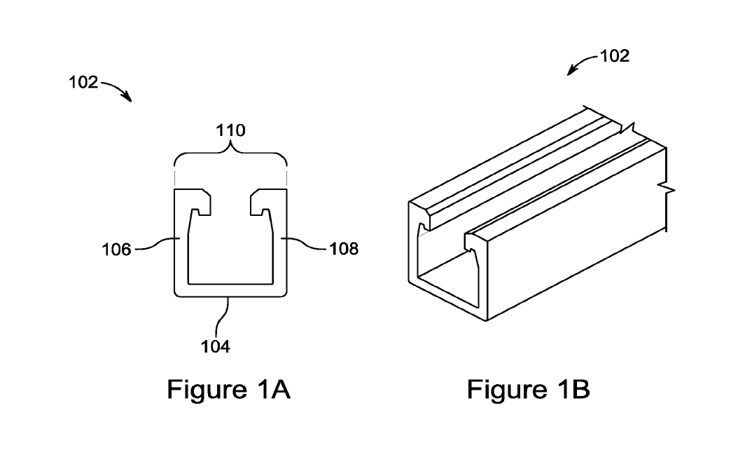

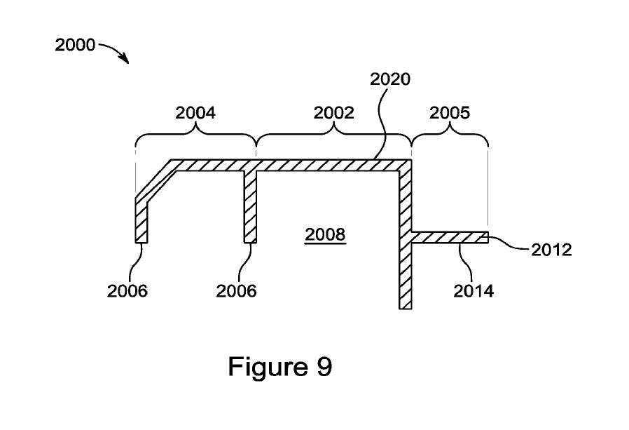

FIGS. 1A and 1B show a support rail 102, according to one embodiment of the present arrangements. Support rail 102 includes a base surface 104 coupled to a first support sidewall 106 and a second support sidewall 108. As shown in FIGS. 1A and 1B, first support sidewall 106 and a second support sidewall 108 are opposing sidewalls having exterior surfaces that define an extending portion 110. As discussed below, in an assembled configuration of present mounting systems, extending portion 110 occupies a receiving cavity (e.g., receiving cavity 1008 of FIG. 8) in the module connector.

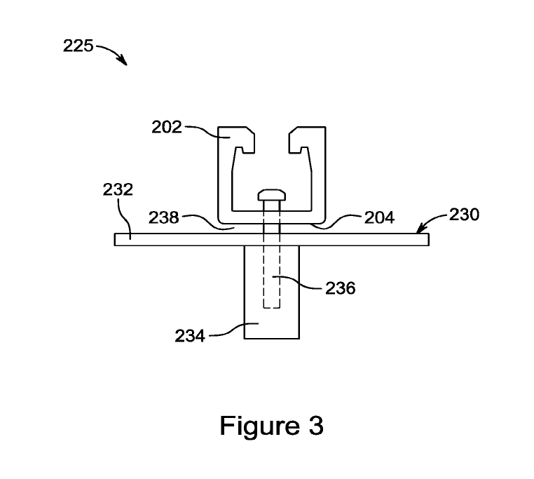

In the embodiment shown in FIGS. 1A and 1B, the inner surfaces of opposing first support sidewall 106 and second support sidewall 108 define a support cavity towards a center region of support rail 102. As explained below, in certain embodiments of the present arrangements, at least a portion of a fastening assembly (e.g., fastener 236 of FIG. 3) resides in or occupies the support cavity and facilitates connection to a support structure and/or associated rails. In one implementation of this design, the fastening assembly specifically attaches base surface 104 to a support structure and/or an associated rafter. Further, in this implementation, base surface 104 may have defined therein one or more apertures, each of which receives at least a portion of the fastening assembly (e.g. connecting pins, lag bolts and screws).

Preferably, support rail 102 includes one or more properties chosen from a group comprising high bending strength, low weight, low cost, fire resistant, corrosion resistant, UV resistant, electrically non-conductive, high strength at low and high temperatures, and low coefficient of thermal expansion. Further, support rail 102 is preferably made from at least one material chosen from a group comprising aluminum, galvanized steel, reinforced plastic with fibers of glass, polymer or carbon. In an even more preferred embodiment of the present arrangements, support rail 102 is made of glass-reinforced pultruded lineals, which includes most, if not all, of the above-listed properties and is easy to drill and cut.

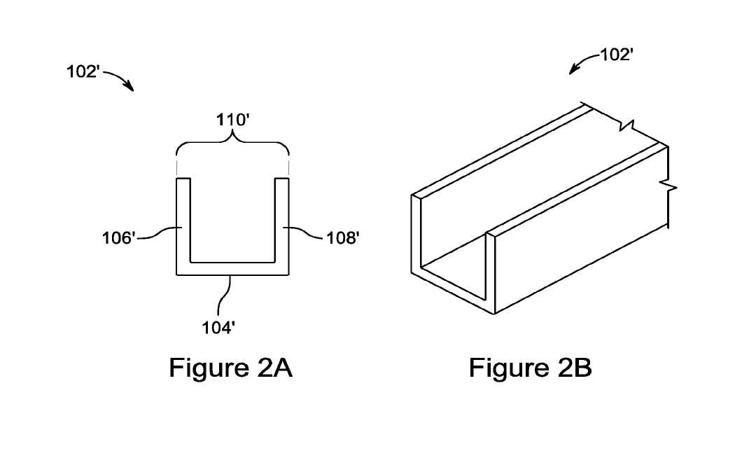

FIGS. 2A and 2B show a support rail 102′, according to another embodiment of the present arrangements. In this embodiment, support rail 102′ includes a base surface 104′, a first support sidewall 106′, a second support sidewall 108′, and an extending portion 110′ that are substantially similar to their counterparts in in FIG. 1A, i.e., support rail 102, base surface 104, first support sidewall 106, second support sidewall 108 and extending portion 110, except first and second support sidewalls 106′ and 108′ do not include an internal lip portion and each of these sidewalls have a uniform thickness along their length. The embodiment shown in FIGS. 2A and 2B uses less material and is easier and/or faster to manufacture (e.g., easily extrude).

In another embodiment of the present arrangements that is different from both the embodiments shown in FIGS. 1A/1B and in FIGS. 2A/2B, a cross-section of support rail 102′ has defined therein a support cavity defined towards a center region. This support cavity may be square or rectangular shaped. In other words, in this embodiment the support rail is akin to square-shaped, hollow tube that extends along a length. One or more apertures defined along a length of this support rail, receive a fastener such that the fastener, from that position, secures base surface 104 to support structure (e.g., support structure 230 of FIG. 3).

FIG. 3 shows a support rail 202 fastened to support structure 230 to form a support connecting subassembly 225. A fastener 236 fastens support rail 202 to support structure 230. Support rail 202 and its base surface 204, as shown in FIG. 3, are substantially similar to support rail 102 and base surface 104 of FIG. 1. In this assembled configuration of the support connecting subassembly, a gap 238 exists between base surface 204 and supporting surface 232. By way of example, gap 238 may be achieved by positioning one or more spacers along the length of support rail 202 between base surface 204 and supporting surface 232. In the presence of an angled supporting surface 232, gap 238 provides space for rainwater and other accumulated material to drain away from the module mounting system. In another embodiment of the present arrangements, base surface 204 is disposed adjacent to and contacts a supporting surface 232 of support structure 230 so that gap 238 does not exist.

Support structures, upon which a module is ultimately secured, may be of different types. One common type of support structure 230 is a rooftop that includes one or more rafters 234. The present arrangements, in one implementation, contemplate disposing support rail 202 above one or more rafters (e.g., rafter 234). A support fastening assembly (e.g., a fastener such as a lag bolt) 236 couples support rail 202 to rafter 234 at one point of intersection (of support rail 202 and rafter 234) to form support connecting subassembly 225. In this configuration, the weight of a module (e.g., a solar module), the mounting system and any downward forces cause by environmental conditions (e.g., wind, rain, and, hail) are distributed to one or more rafters.

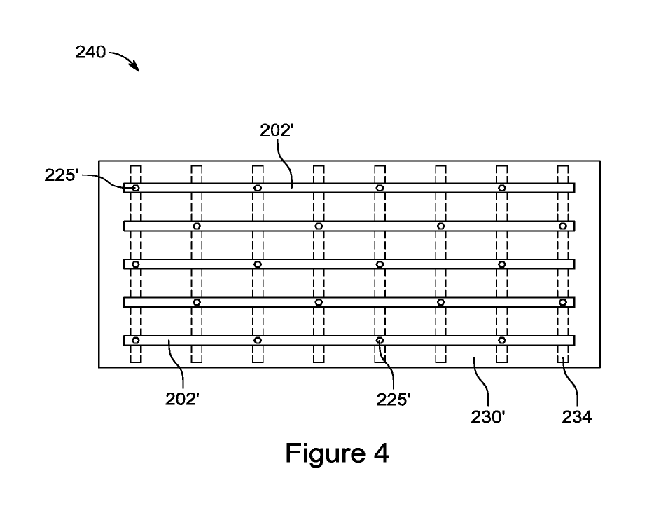

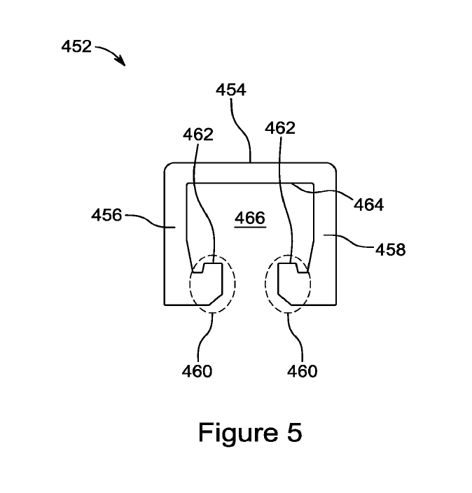

FIG. 4 shows a top view of a mounting subassembly 240 that includes one or more longitudinally extending support rails 202′ that are designed to receive an array of modules. By way of example, module rails and/or module connectors, which are discussed in greater detail in connection with FIGS. 5-10, 11A and 11B, are used to connect modules to one or more of longitudinally extending support rails 202′ of FIG. 4. Each support rail 202′ includes one or more support connecting subassemblies 225′ that connect support rail 202′ to support structure 230′. Thus, using mounting subassembly 240 numerous modules are disposed adjacent to each other with minimal spaces therebetween and in a grid-like fashion above a support structure. In other words, mounting subassembly 240 allows an array of solar panels to be effectively secured to a support structure without consuming an inordinately large amount of space, a drawback of the conventional module mounting systems. This design feature of the present module mounting systems allow, for example, numerous solar panels to harness a maximum amount of solar power to properly exploit the advantages of renewable solar energy.

In mounting subassembly 240, rafters 234 (shown by dotted lines) of support structure 230′ (and corresponding rafters) extend in a direction that is perpendicular to longitudinally extending support rails 202′ and alternate ones of rafters 234 have installed thereon support connecting subassembly 225′, which is shown in greater detail in FIG. 3. However, the present arrangements are not so limited. Support connecting subassembly 225′ may be installed on any of the rafters 234 so long as support rail 202′ is secured to supporting surface 230′.

FIG. 5 shows a module rail 452, according to one embodiment of the present arrangements and that includes a module contacting surface 454, a first module sidewall 456, and a second module sidewall 458. In an assembled configuration, module contacting surface 454 is coupled to or secured to a portion of a module (e.g., a solar module). Module rail 452 also includes a channel cavity 466, extending along a length of module rail 452. As shown in FIG. 5, channel cavity is defined by an engaging surface 464 and surfaces of first module sidewall 456, and second module sidewall 458.

Each of first module sidewall 456 and second module sidewall 458 include an internal lip feature 460 that extend towards channel cavity 466. Specifically, as shown in FIG. 5, the open edges of internal lip feature 460 have a curved profile that bend towards channel cavity 466.

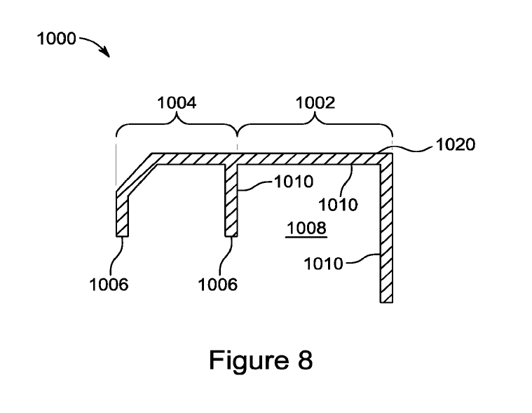

Importantly in the embodiment of FIG. 5, a locking surface 462 is defined at the end of each internal lip feature 460. In one preferred embodiment of the present arrangements, wherein a plurality of locking surfaces are being used, each locking surface has the same height, i.e., each locking surface extends to the same plane that is parallel to engaging surface 464. As will be explained later, in an assembled configuration of the present mounting systems, module rail 452 couples to a module connector (e.g., module connector 1000 of FIG. 7) such that each locking surface 462 and/or engaging surface 464 engages or couples with corresponding ones of a lockable surface (e.g., lockable surface 1006 of FIG. 8) and contacting surface (e.g., contacting surface 1020 of FIG. 8), respectively. Stated another way, engagement or coupling of each locking surface 462 and/or engaging surface 464 with corresponding ones of a lockable surface (e.g., lockable surface 1006 of FIG. 8) and contacting surface (e.g., contacting surface 1020 of FIG. 8), respectively, generates a locking mechanism that locks module connector (e.g., module connector 1000 of FIG. 7) into place with module rail 452 of FIG. 5.

FIG. 5 shows one embodiment of module rail 452. However, the present arrangements are not so limited. By way of example, module rail 452 may include a single sidewall (i.e., first module sidewall 456 having an internal lip feature 460 and accompanying locking surface 462). In this configuration, module rail 452 receives a module connector and locking surface 462 and engaging surface 464 engage with the lockable surface and the contacting surface of the module connector. As another example, internal lip features 460 of first module sidewall 456 and second module sidewall 458 connect to form an enclosed, or hollow, module rail 452. In this example, the module rail has a square or rectangular tube-like appearance. Consequently, locking surface 462 may extend along a portion or the entire length of module rail 452 and is on an opposing internal surface to engaging surface 462. In a configuration where the module rail couples to the module connector, a locking surface of the module rail engages or couples to a lockable surface of the module connector along the entire length or a portion of the module connector to form a very strong connection between the module rail and the module connector. According to the present arrangements, such strong connections allow a plurality of module connectors to be connected to a single module rail.

Module rail 452 may be selected from the same material group as support rail 102. However, it is preferable for module rail 452 to be electrically non-conductive to prevent an electrical path to the ground. In one preferred embodiment of the present arrangements, module rail 452 is made from the same or similar material as the material of the module's contacting surface, i.e., the surface of the module that directly contacts the module rail. In this embodiment, module rail 452 and the module's contacting surface, preferably, have similar coefficients of thermal expansion as this tends to reduce stresses that may develop when the present mounting systems, during use, are subjected to a broad range of temperatures.

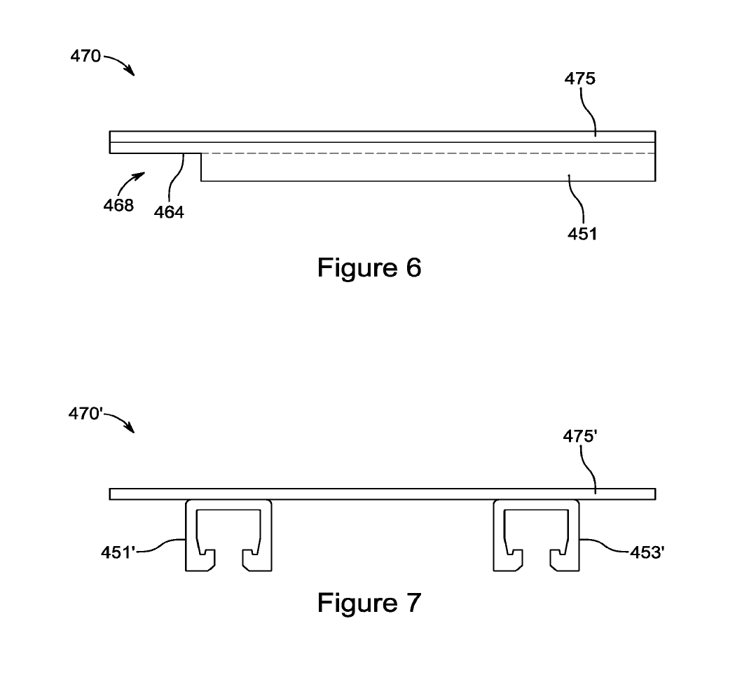

FIG. 6 shows a side-sectional view of a module subassembly 470 that includes a longitudinally extending module rail 451 and at least a portion of a module 475 (e.g., solar module). Module rail 451 is substantially similar to module rail 452 of FIG. 5, except module rail 451 has defined, at one end, a notch 468. As shown in FIG. 6, notch 468 excludes a portion of the sidewalls of module rail 451 (e.g., excludes a portion of first module sidewall 456 and second module sidewall 458 of FIG. 5). Further, notch 468 includes an engaging surface 464, which is also shown in connection with module rail 452 in FIG. 5. In an assembled configuration of the present mounting systems, a module connector's contacting surface may engage with engaging surface 464 of notch 468. As will be explained later in connection with a mounting subassembly, notch 468 facilitates connection of one module rail with another module rail and is designed to receive a support rail (e.g., support rail 202 of FIG. 2). Notch 468, therefore, may couple and support two adjacent solar modules and may serve as a location for coupling to a support rail.

FIG. 7 shows a cross-sectional view of a module subassembly 470′ that includes module rails 451′ and 453′ coupled to a portion of module 475′. Module rails 451′ and 453′ are substantially similar to module rail 452 of FIG. 4. The present arrangements recognize that module subassembly 470′ may have any number of module rails, which function to support the weight of one or more attached modules and any additional weight caused by environmental conditions. Module rails may also provide rigidity to one or more of the attached modules. When used in combination with a rectangular solar module the number of rails may depend on the orientation in which the solar module is to be installed. By way of example, for an installation in which the longer edge of the solar module is longitudinal, three vertical rails may be installed along a length of the solar module. However, for an installation in which the longer edge of the solar module runs perpendicular to the longitudinal extension of the solar module, two vertical rails may be installed along the length of the solar module.

FIG. 8 shows a module connector 1000, according to one embodiment of the present arrangements and that includes a support rail receiving portion 1002, a connecting portion 1004, and a contacting surface 1020 (which is an exterior surface of connecting portion 1004). Module connector 1000 extends longitudinally. Further, contacting surface 1020 of module connector 1000 couple to or engages with engaging surface 464 along a length of module rail 452 shown in FIG. 5.

In one embodiment of the present arrangements, connecting portion 1004 of module connector 1000 of FIG. 8 includes sidewalls that have, at a location approximate to an end of the sidewalls, one or more lockable surfaces 1006 that engage with the locking surfaces (e.g., locking surfaces 462 shown in FIG. 5) of module rail (e.g., module rail shown in FIG. 5).

In addition to engaging with one or more module rails, module connector 1000 may also engage with a support rail (e.g., support rail 102 shown in FIG. 1). This may be accomplished many number of ways. In one preferred embodiment of the present arrangements, support rail receiving portion 1002 of module connector 1000 of FIG. 8 includes one or more inner receiving surfaces 1010 that define a receiving cavity 1008. In module connector 1000, preferably, two or more receiving sidewalls that are disposed opposite to each other define inner receiving surface 1010. During an assembled configuration of the present mounting systems, receiving cavity 1008 is designed to receive an extending portion (e.g., extending portion 110 of FIG. 1A) of a support rail (e.g., support rail 102 of FIG. 1A). In an assembled configuration of the present mountings systems, one or more of inner receiving surfaces 1010 may be disposed adjacent to and contacting extending portions 110 of support rail 102 of FIG. 1A. Preferably, a fastening mechanism fastens the receiving surfaces of the receiving cavity to the extending portions of the support rail further strengthening the connection between the ultimately used support structure, through support connecting subassembly (e.g., support connecting subassembly 225 of FIG. 3) and the module connector, which ultimately connects to a module.

Module connector 1000 may be selected from the same material list as support rail 102. In one preferred embodiment of the present arrangements, module connector 1000 is made of aluminum.

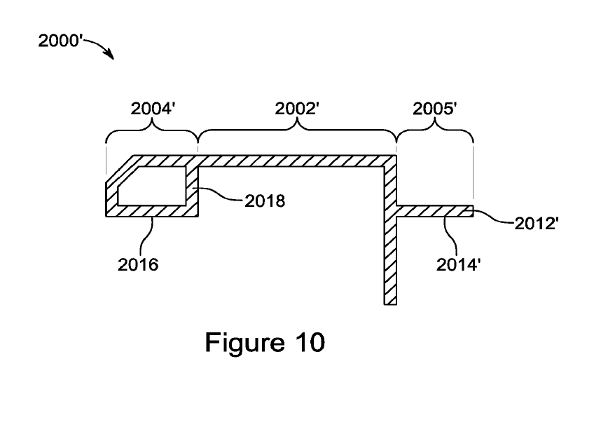

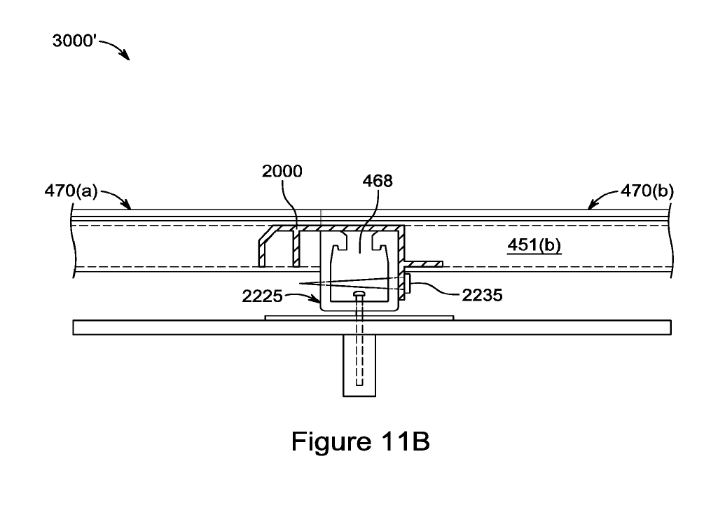

FIG. 9 shows module connector 2000, according to another embodiment of the present arrangements and that, in addition to a receiving cavity 2008, includes at least one connecting portion 2005. Module fastener 2000 is substantially similar to module connector 1000 of FIG. 7 (i.e., module fastener 2000 includes a support rail receiving portion 2002, a connecting portion 2004, a lockable surface 2006, and a receiving cavity 2008 that are substantially similar to support rail receiving portion 1002, connecting portion 1004, lockable surface 1006, and receiving cavity 1008 of FIG. 7). As shown in FIG. 9, in addition to connecting portion 2004, module connector 2000 includes another connecting portion 2005, which, in turn, includes a connector fin 2012 having associated lockable surfaces 2014. During an assembled configuration of the present mounting systems and similar to lockable surfaces 2006 of connecting portion 2004, lockable surfaces 2014 of another connecting portion 2005 engage with the locking surfaces (e.g., locking surfaces 462 shown in FIG. 5) of a module rail (e.g., module rail shown in FIG. 5). Thus, in an assembled configuration of the present mounting systems, the lockable surfaces associated with the two different connecting portions engage with the locking surfaces of the same or two different module rails to engage with that or two different module rails. In the configuration where the lockable surfaces associated with two different connecting portions engage with locking surfaces of two different module rails, the lockable surfaces allow coupling of two different modules that are ultimately secured on the two different module rails. Further, each of the contacting surfaces associated with the connecting portion (e.g., connecting portion 2004) and the support rails receiving portion (e.g., support rail receiving portion 2002) contact or engage with the same or two different engaging surfaces (e.g., engaging surface 465 of FIG. 5) associated with one or two different module rails to form a stronger coupling or connection between module connector 2000 and one or two different module rails. Such couplings between a module connector and the same or two different module rails is explained in greater detail below in connection with FIGS. 11A and 11B.

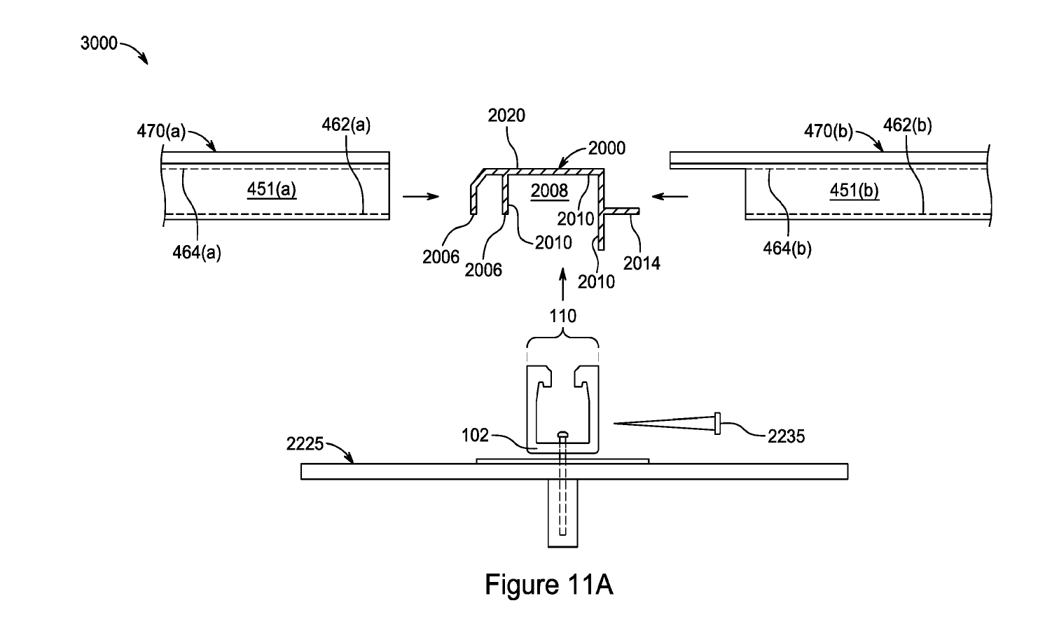

FIG. 10 shows module connector 2000′, according to yet another embodiment of the present arrangements and that includes a connecting portion 2004′ that is different than connecting portion 2004 of FIG. 9. Module connector 2000′ of FIG. 10 is substantially similar to module connector 2000 of FIG. 9 (i.e., module fastener 2000′ includes a support rail receiving portion 2002′, a connecting portion 2004′, another connecting portion 2005′, a connector fin 2012′, and another lockable surfaces 2014′ that are substantially similar to support rail receiving portion 2002, connecting portion 2004, another connecting portion 2005, connector fin 2012, and another lockable surfaces 2014 of FIG. 9). The difference between module connectors 2000′ and 2000 of FIGS. 10 and 9, respectively, is that connecting portion 2004′ of module connector 2000′ includes a framed structure 2018, which has defined thereon a framed lockable surface 2016, and connecting portion 2004 does not have such a framed structure and framed lockable surface. In an assembled configuration of the present mounting systems, framed lockable surface 2016 couples to or engages with a locking surface (e.g., locking surface 462 of FIG. 5) of a module rail (e.g., module rail shown in FIG. 5).

Framed structure 2018 of FIG. 10 contributes to the strength of the connection or coupling between module connector 2000′ and one or more module rails (e.g., module rail 452 shown in FIG. 5). By way of example, the rigidity of framed structure 2018 allows framed lockable surface 2016 to effectively resist deflection produced by locking surfaces of the module rails, during an assembled state of the present mounting systems, by. Furthermore, an increased length of lockable surface 2016 is designed to engaged with a greater length of the locking surface of the module rail (e.g., locking surface 462 of FIG. 5) of a module rail (e.g., module rail shown in FIG. 5). In certain embodiments of the present arrangements, connecting portions 2004 and 2004′ of FIGS. 9 and 10 are absent, and in these embodiments, presence of connector fin 2012 of FIG. 9 or 2012′ of 10 is present along with support rail receiving portion 2002 of FIGS. 9 and 2002′ of FIG. 10 to facilitate forming a locking connection or coupling between module connector 2000 and 2000′ of FIGS. 9 and 10 and a module rail (e.g., module rail 452 of FIG. 5).

FIG. 11A shows an exploded view of a mounting system subassembly 3000, according to one embodiment of the present arrangements and that includes two module subassemblies 470(a) and 470(b), a module connector 2000, and support connecting subassembly 2225. Module subassemblies 470(a) and 470(b), which include module rails 451(a) and 451(b), respectively, are substantially similar to module subassembly 470, which includes module rail 451 of FIG. 6. Module connector 2000 of FIG. 11A is the same as shown in FIG. 9. Furthermore, support connecting subassembly 2225 is substantially similar to support connecting subassembly 225 of FIG. 2.

In an assembled configuration of mounting system subassembly 3000, module connector 2000 is inserted into a cavity (e.g., channel cavity 466 of FIG. 5) of a module rail (e.g., module rail 452 of FIG. 5). In FIG. 11A, module connector 2000 is inserted into each of the channel cavities associated with module subassemblies 470(a) and 470(b), which are substantially similar to module subassembly 470 of FIG. 6. More specifically, in this inserted configuration, contacting surface 2020 of module connector 2000 engages with engaging surface 464(a) of module rail 451(a) and lockable surface 2006 of module connector 2000 engages with locking surface 462(a) of module rail 451(a). Similarly, contacting surface 2020 of module connector 2000 engages with engaging surface 464(b) of module rail 451(b) and lockable surface 2014 of module connector 2000 engages with locking surface 462(b) of module rail 451(b). Thus, one portion of module connector 2000 is secured within module rail 451(a) and another portion of module connector 2000 is secured within 451(b). Each module rails 451(a) and 451(b) may have at least two locations of contact with module connector 2000. The first location of contact with module connector 2000 is along their associated engaging surfaces (e.g., engaging surface 464(a) of module rail 451(a) and engaging surface 464(b) of module rail 451(b)). The second location of contact with module connector 2000 is at their associated locking surfaces (e.g., locking surface 462(a) of module rail 451(a) and locking surface 462(b) of module rail 451(b)).

In addition to engaging with module subassemblies 470(a) and 470(b), module connector 2000 also engages with support connecting subassembly 2225. To this end, an extending portion 110 of support rail 102 is received inside receiving cavity 2008. In one embodiment of the present arrangements, the dimensions of inner receiving surfaces 2010 are slightly larger than the dimension of extending portion 110 such that extending portion 110 is secured inside one of inner receiving surfaces 2010.

In another embodiment of the present arrangements, one or more inner receiving surfaces 2010 secures extending portion 110 by forming a frictional contact between one or more inner receiving surfaces 2010 and extending portion 110. In yet another embodiment of the present arrangements, a fastener 2235 engages with extending portion 110 and one or more inner receiving surfaces 2010 to secure module connector 2000 to support connecting subassembly 2225.

FIG. 11B shows a mounting system subassembly 3000′, which is a depiction of an assembled state of mounting system subassembly 3000 of FIG. 11A. It is clear from this figure, and as explained above in FIG. 11A, that a portion of module connector 2000 engages with module subassemblies 470(a) and a different portion of module connector 2000 engages with 470(b) such that the module connector 2000 couples these two module subassemblies together.

Specifically, at least a portion of support rail receiving portion (e.g., support rail receiving portion 2002 of FIG. 9) of module connector 2000 is positioned inside a notch (e.g., notch 468 of 11B) that is defined on a module rail (e.g., module rail 451 of FIG. 6) of module subassembly 471(b). In one embodiment of the present arrangements, another portion of support rail receiving portion (e.g., support rail receiving portion 2002 of FIG. 9) of module connector 2000 is positioned inside a channel cavity (e.g., channel cavity 466 of FIG. 5) of module rail (e.g., module 452 of FIG. 5) associated with module subassembly 470(a). With regard to the remaining connecting portions (e.g., connecting portion 2004 and another connecting portion 2005 of FIG. 9, respectively), as explained above, the lockable surfaces (e.g., lockable surfaces 2006 and 2014 of FIG. 11A) of are in a locked position with locking surfaces (e.g., locking surfaces 462(a) and (b) of FIG. 11A) of module rails (e.g., module rails 451(a) and 451(b)). Further, a fastener 2235 may be used to further strengthen the coupling or connection between support connecting subassembly 2225 and module connector 2000. In the assembled configuration of mounting system subassembly 3000′, a support connecting subassembly (e.g., support connecting subassembly 2225 of FIG. 11B) longitudinally extends and is secured inside a module connector (e.g., module connector 2000 of FIG. 11B) that extends preferably a width of one or more module rails (e.g., module rail 451(a) and 451(b)). One or more of these module rails extend in another direction, preferably, perpendicular to the longitudinally extending support connecting subassembly. As a result and as explained above in connection with FIG. 4, many module rails are supported on one or more support rails of a mounting subassembly (e.g., mounting subassembly 240 of FIG. 4). One or more module rails, in turn, supports one or more modules.

According to one embodiment of the present arrangements, different module connector designs (e.g., FIGS. 8, 9 and 10) are employed with respect to a particular support connecting subassembly (e.g., support connecting subassembly 225 of FIG. 3), depending where that support connecting subassembly is disposed, whether the module subassembly has a notch, how many modules/module subassemblies are being coupled approximately on that particular support connecting subassembly, or the weight of the modules/module subassemblies that are being supported atop the particular support connecting subassembly.

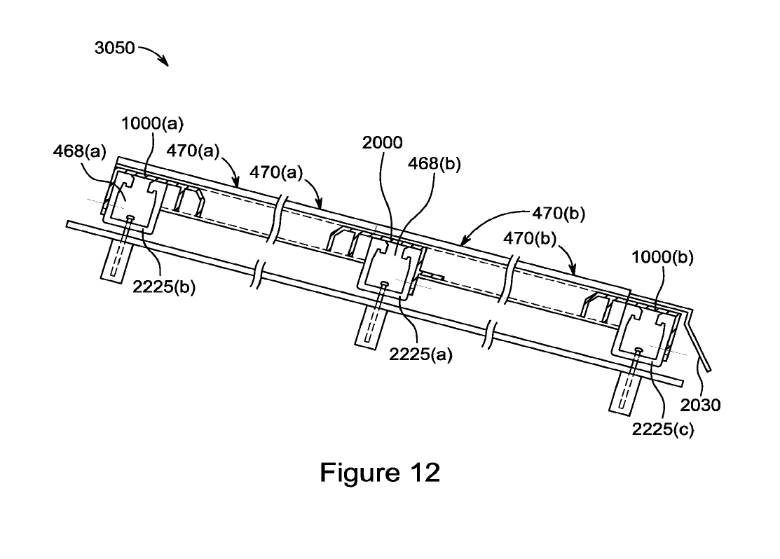

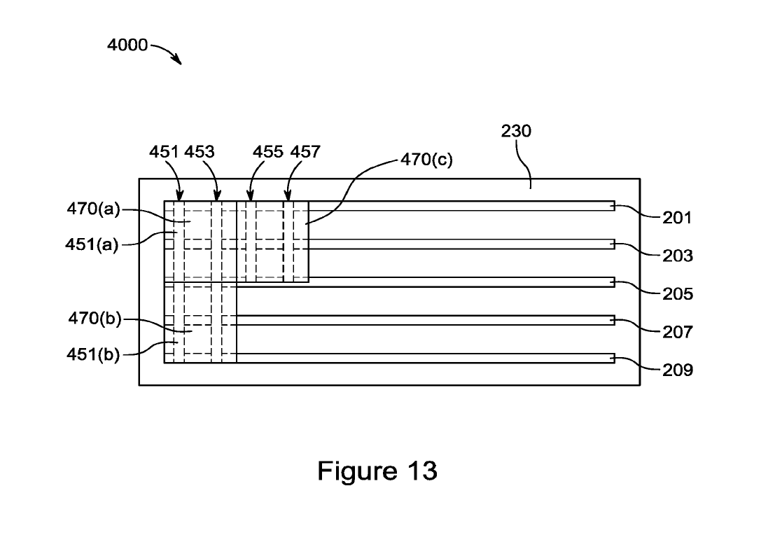

FIG. 12 shows a partially arranged mounting system 3050, according to one embodiment of the present arrangements. This partial arrangement is an exemplar that uses two different type of module connectors depending on their function. In this figure, module connectors of a first type 1000(a) and 1000(b) are used at either end points of a continuous module rail (e.g., module rail 451 of FIG. 13). As shown in FIG. 12, a module connector of a second type 2000 is used to couple together two different type of module subassemblies 470(a) and 470(b) and also secure them above support connecting subassembly 2225(a). Support connecting subassembly 2225(a) and module subassemblies 470(a) and 470(b) are the same as they are shown in FIG. 11A and support connecting subassemblies 2225(a), 2225(b), and 2225(c) are substantially similar to each other.

Module connectors of the first type 1000(a) and 1000(b) do not include connector fins (e.g., connector fin 2014 of FIG. 9), as they are shown in connection with module connector 2000. According to the present arrangements, connector fins need not be included when the module connector is being used adjacent to support connecting assemblies located at an end point of a continuous module rail.

Although the module connectors 1000(a) and 1000(b) are of the same type, they form a different type of connection with their associated module subassemblies 470(a) and (b). By way of example, module connector 1000(a) is received inside a notch 468(a) defined at one end of module subassembly 470(a), but it is not necessary to have a notch defined at the other end of module subassembly 470(b) to receive module connector 1000(b). At the other end of module subassembly 470(b) module connector 1000(b) is inserted into a channel cavity (e.g., channel cavity 466 of FIG. 5) of a module rail (e.g., module rail 452 of FIG. 5) and this type of insertion/engagement creates a sufficiently strong connection to connect the module subassembly 470(b) to its associated underlying support connecting subassembly 2225(c). To the extent additional security is required, a fastening mechanism may be used to secure module connectors 1000(a) or 1000(b) to support connecting subassemblies 2225(b) and 2225(c).

Mounting system 3050 also provides provisions for protection from environmental conditions. Specifically, flashing 2030 may be coupled to module subassembly 470(b) and/or module connector 1000(b) and extend to a supporting surface to cover and/or protect support connecting subassembly 2225(c) from environmental conditions during use.

FIG. 13 shows a present mounting system 4000, according to one embodiment of the present arrangements. Mounting system 400 includes a plurality of modules installed on a plurality of module subassemblies (e.g., module subassemblies 470(a), 470(b), and 470(c)) that are secured on a mounting subassembly (e.g., mounting subassembly 240 of FIG. 3). As explained in FIG. 4, one or more support rails (e.g., support rails 202′ of FIG. 4) are coupled to a support structure (e.g., support structure 230 of FIG. 3). As a result, one or more modules (e.g., solar modules) are ultimately securely fastened to a support structure 230 (e.g., rooftop 230 that is supported by rafters 234 of FIG. 3).

As shown in FIG. 13, a plurality of module rails (e.g., module rails 451(a) and 451(b)) connects to form continuous module rail 451. FIGS. 11A and 11B show that one or more module connectors (e.g., module connector 2000 of FIG. 9) may be used to connect module rails 451(a) and 451(b). Other module rails may similarly connect to form continuous module rails 453, 455, and 457. Continuous module rails 451, 453, 455, and 457 are perpendicular to support rails 201, 202, 205, 207, and 209 (which are substantially similar to support rail 202 of FIG. 2). In one preferred embodiment of the present arrangements, continuous module rails 453, 455, and 457 are parallel to the underlying rafters (e.g., rafters 234 of FIG. 3) when the presenting mounting systems are assembled on a rooftop.

The present mounting systems offer many advantages over their conventional counterparts. By way of example, present mounting system 4000 allow a plurality of modules to be disposed adjacent to each other without a minimal or no gap between adjacent modules. As a result, the amount of extensive space needed by the conventional mounting systems to install modules is obviated and a significantly greater number of modules may be installed per square feet of rooftop surface. As another example, one or more module connector couples strong subassemblies, i.e., a mounting subassembly and one or more module subassemblies, to form a mounting system that has great mechanical strength to overcome the challenges posed by the environmental conditions and inclement weather elements. Moreover, the present mounting systems represents a lightweight design that lowers transport and installation costs. The risks of having a heavy object installed on a rooftop are also eliminated.

The present teachings also provide novel processes of mounting a module (e.g., a solar module) using the mounting system of the present arrangements. In one embodiment of the present teachings, the process preferably begins with a step of obtaining one or more module rails (e.g., one or more module rails 452 of FIG. 5 and module rail 451 of FIG. 6). Preferably, each module rail includes an engaging surface and sidewalls that are configured to define, inside each of the module rail, a channel cavity. In one embodiment of the present teachings, each sidewall includes an internal lip features that extend inside and along a length of the channel cavity. The internal lip features define one or more locking surfaces. In yet another embodiment of the present teachings, a portion of module rail includes a notch (e.g., notch 468 of FIG. 6), which in an assembled configuration is designed to receive an extending portion (e.g., extending portion 110 of FIG. 1A) of the support rail (e.g., support rail 102 of FIG. 1A).

Another step includes securing one or more of module rails to one or more modules to form one or more module subassemblies (e.g., module subassembly 470 of FIG. 5). In certain embodiments of the present teachings, each module subassembly includes two or more module rails.

A next step includes obtaining one or more support rails, each of which includes an extending portion. Another step includes coupling one or more support rails to a support structure to form one or more support connecting subassemblies (e.g., support connecting subassembly 225 of FIG. 2). A fastening mechanism (e.g., fastener 236 of FIG. 3) may secure each support rail to the support structure. In a preferred embodiment of the present teachings, one or more rafters (e.g., rafter 234 of FIG. 2) provide mechanical support to the support rails.

The mounting process proceeds to a step of connecting one or more module subassemblies and one or more support connecting subassemblies. A module connector connects a module subassembly to a support connecting subassembly. Each module connectors includes a support structure receiving portion that has defined therein a receiving cavity having inner receiving surfaces. Module connector also includes an outer boundary of a contacting surface and includes one or more connecting portions, each of which includes one or more lockable surfaces.

The step of connecting a module subassembly and a support connecting subassembly includes inserting a module connector into one or more module rails such that contacting surface of the module connector contacts the engaging surface of one and/or another module rail. In this inserted position, one or more lockable surfaces of the module connector engages with one or more locking surfaces of one and/or another module rail to lock the module connector inside one and/or another adjacent module rails.

The step of connecting a module subassembly and a support connecting subassembly also includes receiving the extending portion of each support rails inside each module connector's receiving cavity such that each module connectors couple to a support attachment rail.

Although illustrative embodiments of the present teachings and arrangements are shown and described in terms of solar modules, other modifications, changes, and substitutions are intended. By way of example, other type of modules, which are different from solar modules, may well be used in connection with the present teachings and arrangements. Accordingly, it is appropriate that the disclosure be construed broadly and in a manner consistent with the scope of the disclosure, as set forth in the following claims.

What is claimed is:

1. A mounting system comprising:
one or more support structure rails (“support rails”), each of which is designed to attach to one or more support structures and includes an extending portion;
one or more module attachment rails (“module rails”), each of which is designed to attach to one or more modules and includes an engaging surface and sidewalls that are configured to define, inside each of said module rail, a channel cavity, and wherein said sidewalls include one or more internal lip features that extend towards and along a length of said channel cavity, and wherein said internal lip features define one or more locking surfaces;
one or more module connectors, each of which is designed to couple at least one of said support rail to at least one of said module rail, and each of said module connectors include a support structure receiving portion having defined therein a receiving cavity having inner receiving surfaces, that further includes an outer boundary of a contacting surface, and that further includes one or more connecting portions, each of which includes one or more lockable surfaces; and
wherein, in an assembled configuration of said mounting system, one or more of said module connectors are inserted into one or more of said module rails such that said contacting surface of each of said module connectors contacts said engaging surface of one and/or another of said module rails and one or more of said lockable surfaces of each of said module connectors engages with one or more of said locking surfaces of one and/or another of said module rails to lock one or more of said module connectors inside one or more of said module rails and wherein said extending portion of each of said support rails is received inside each of said receiving cavity of each of said module connectors such that one or more of said module connectors couple to one or more of said support attachment rails.

2. The mounting system of claim 1, wherein said support structure is a rafter of a roof structure and, in an attached configuration of said support structure and said support rail, said support rail is disposed in a direction that is perpendicular to the extending direction of said rafter.

3. The mounting system of claim 2, wherein, said support rail is secured to multiple rafters.

4. The mounting system of claim 1, wherein said extending portion has protruding sidewalls that are designed to contact said inner receiving surfaces of said module connector.

5. The mounting system of claim 4, wherein dimensions of said inner receiving surfaces of said module connector are slightly larger than dimensions of said protruding sidewalls such that each of said protruding sidewalls is secured inside one of said inner receiving surfaces by frictional contact and/or each of said protruding sidewalls is secured inside said inner receiving surfaces by a fastening assembly that fastens one of said protruding sidewalls to one of said inner receiving surfaces.

6. The mounting system of claim 1, wherein approximate open edges of said extending portion includes one or more support internal lip features that includes a curved profile bending towards said extending portion and/or simple profile that does not include a curved profile.

7. The mounting system of claim 1, further comprising a support fastening assembly that fastens said support rail to said support structure such a space is defined between said support rail and said support structure to allows for moisture or rain to travel.

8. The mounting system of claim 1, wherein said internal lip features of said module rail includes open edges having a curved profile that bends towards said extending portion.

9. The mounting system of claim 1, wherein one end of one of said module rail includes a notch to facilitate connection with another of said module rail and is designed to receive said support rail.

10. The mounting system of claim 1, wherein module rail is fastened to a solar module using a module fastening assembly.

11. The mounting system of claim 1, wherein each of said module connectors includes a first connection portion having a connector fin, which has one or more lockable surfaces and in assembled configuration of one of said module connector and one of said module rail, one or more lockable surfaces engage with one or more of said locking surfaces of said module rail.

12. The mounting system of claim 1, wherein each of said module connectors includes a second connection portion having an additional contacting surface and external sidewalls, which have, at a location approximate to an end, one or more additional lockable surfaces and in assembled configuration of one of said module connector and one of said module rail, one or more of said additional lockable surfaces engage with one or more of said locking surfaces of said module rail.

13. The mounting system of claim 1, wherein said inner receiving surface is defined by two or more opposing sidewalls.

14. The mounting system of claim 1, wherein said contacting surface of each of said module connectors contacts said engaging surface of one said module rails.

15. The mounting system of claim 1, wherein one or more of said lockable surfaces of each of said module connectors engages with one or more locking surfaces of one of said module rails.

16. The mounting system of claim 1, wherein said contacting surface of each of said module connectors contacts said engaging surfaces of one and of another of said module rails.

17. The mounting system of claim 1, wherein one or more of said lockable surfaces of each of said module connectors engages with one or more locking surfaces of one and of another of said module rails.

18. A process of mounting a module, said process comprising:
obtaining one or more module rails, each of which includes an engaging surface and sidewalls that are configured to define, inside each of said module rail, a channel cavity, and wherein said sidewalls include one or more internal lip features that extend towards and along a length of said channel cavity, and wherein said internal lip features define one or more locking surfaces;
securing to one or more modules one or more of said module rails to form one or more module connecting sub-assemblies;
obtaining one or more support rails, each of which includes an extending portion;
coupling to one or more support structures one or more of said support structure attachment rails for form one or more support connecting subassemblies;
connecting, using one or more module connectors, one or more of said module subassemblies and one or more of said support connecting subassemblies, and wherein each of said module connectors includes a support structure receiving portion that has defined therein a receiving cavity having inner receiving surfaces, that further includes an outer boundary of a contacting surface, and that further includes one or more connecting portions, each of which includes one or more lockable surfaces;
wherein, said connecting includes inserting one or more of said module connectors into one or more of said module rails such that said contacting surface of each of said module connectors contacts said engaging surface of one and/or another of said module rails and one or more of said lockable surfaces of each of said module connectors engages with one or more of said locking surfaces of one and/or another of said module rails to lock one or more of said module connectors inside one or more of said module rails,
wherein said connecting further includes receiving said extending portion of each of said support rails inside each of said receiving cavity of each of said module connectors such that one or more of said module connectors couple to one or more of said support attachment rails.

19. The process of mounting said module of claim 18, wherein said coupling or said securing involves using an adhesive and/or a fastening assembly.
